(19) United States
(12) Patent Application Publication
(10) Pub. No.: US 2021/0012701 A1
(43) Pub. Date: Jan. 14, 2021

(54) DISPLAY PANEL

(71) Applicant: WUHAN CHINA STAR OPTOELECTRONICS SEMICONDUCTOR DISPLAY TECHNOLOGY CO., LTD., Wuhan, Hubei (CN)

(72) Inventor: Sisi ZHOU, Wuhan, Hubei (CN)

(21) Appl. No.: 16/630,448

(22) PCT Filed: Sep. 20, 2019
(86) PCT No.: PCT/CN2019/107003

§ 371 Date: Jan. 12, 2020

(30) Foreign Application Priority Data
Jul. 8, 2019 (CN) 201910609598.7

(51) Int. Cl. G09G 3/20

(52) U.S. Cl. CPC G09G 3/2092; G09G 2310/0275; G09G 2330/12

(57) ABSTRACT

The present invention discloses a display panel. The display panel comprises a plurality of test data ports. The plurality of test data ports are connected to a data line within the display panel transfer test data to the display panel. Wherein, the display panel further comprises a plurality of fixed resistors, any two adjacent test data ports connect through the fixed resistors, and values of the fixed resistors are greater than or equal to 1000 ohms.

### FIELD OF INVENTION

The disclosure relates to the electronic display technology field, and more particularly to a display panel.

### BACKGROUND OF INVENTION

In the manufacturing process of display panels, constant monitoring of product quality issues is needed, so that unqualified products can immediately be screened out. At the same time, links in manufacturing process that are prone to problems or risks can be understood through monitoring results. For example, currently, before modules are assembled, panels need to undergo cell test, and only panels with normal screen display function will go to the next stage for assembly. Referring to FIG. 1, FIG. 1 is a circuit diagram of a panel port for performing cell test. Wherein, the cell test signal comprises a red test signal, a red test enable signal, a green test signal, a green test enable signal, a blue test signal and a blue test enable signal, which are received to by a display panel through six test ports. After the test is over, a high voltage signal needs to be received by the test signal port to disable the test ports, so that the display panel can display normally.

### SUMMARY OF INVENTION

In the prior art, due to abnormal port lines, etc., the high voltage cannot be received to the test signal port. If some of the test signals cannot be received to the high voltage signal, the corresponding display signal cannot be received to the display panel, which causes abnormal display.

The object of the present disclosure is to provide a display panel to resolve the technical issue that the display signal cannot be received to the display panel after the cell test.

To achieve the above object, the present disclosure provides a display panel, comprising a plurality of test data ports connected to a data line within the display panel and transferring test data to the display panel; wherein, the display panel comprises a plurality of fixed resistors, and any two adjacent test data ports are connected through the fixed resistor, values of fixed resistor is greater than or equal to 1000 ohms; wherein, the plurality of fixed resistors are formed in series.

According to one aspect of the present disclosure, the number of the test data ports is N, the number of the fixed resistor are N-1, wherein N is positive integer and greater than or equal to 2.

According to one aspect of the present disclosure, the display panel comprises a plurality of display data ports, the plurality of display data ports are connected to the data line within display panel and transferring test data to the display panel, wherein each of the data lines is corresponding to each of the test data port and each of the display data port, and the test data port and the display data port are formed in parallel in the same data line.

According to one aspect of the present disclosure, the test data port comprises a plurality of first enable ports and a plurality of first display ports.

According to one aspect of the present disclosure, the plurality of first enable signal ports comprises: a first red enable signal port receiving a first red enable signal and connected to a first data line; a first green enable signal port receiving a first green enable signal and connected to a second data line; a first blue enable signal port receiving a first blue enable signal and connected to a third data line.

According to one aspect of the present disclosure, the plurality of first display signal ports comprises: a first red display signal port, receiving a first red display signal and connected to a fourth data line; a first green display signal port, receiving a first green display signal and connected to a fifth data line; a first blue display signal port, receiving a first blue display signal and connected to a sixth data line.

According to one aspect of the present disclosure, the plurality of fixed resistors comprises: a first fixed resistor used for connecting to the first red enable signal port and the first green enable signal port; a second fixed resistor used for connecting to the first green enable signal port and the first blue enable signal port; a third fixed resistor used for connecting to the first blue enable signal port and the first red display signal port; a fourth fixed resistor used for connecting to the first red display signal port and the first green display signal port; a fifth fixed resistor used for connecting to the first green display signal port and the first blue display signal port.

According to one aspect of the present disclosure, wherein values of the plurality of fixed resistor are equal.

According to one aspect of the present disclosure, wherein values of the plurality of constants resistor are greater than or equal to 3000 ohms and less than or equal to 100000 ohms.

To achieve the above object, the present disclosure provides a display panel, comprising a plurality of test data ports connected to a data line within the display panel and transferring test data to the display panel; wherein, the display panel comprises a plurality of fixed resistors, and any two adjacent test data ports are connected through the fixed resistor, values of fixed resistor is greater than or equal to 1000 ohms.

According to one aspect of the present disclosure, the number of the test data ports is N, the number of the fixed resistor are N-1, wherein N is positive integer and greater than or equal to 2.

According to one aspect of the present disclosure, the display panel comprises a plurality of display data ports, the plurality of display data ports are connected to the data line within display panel and transferring test data to the display panel, wherein each of the data lines is corresponding to each of the test data port and each of the display data port, and the test data port and the display data port are formed in parallel in the same data line.

According to one aspect of the present disclosure, the test data port comprises a plurality of first enable ports and a plurality of first display ports.

According to one aspect of the present disclosure, the plurality of first enable signal ports comprises: a first red enable signal port receiving a first red enable signal and connected to a first data line; a first green enable signal port receiving a first green enable signal and connected to a second data line; a first blue enable signal port receiving a first blue enable signal and connected to a third data line.

According to one aspect of the present disclosure, the plurality of first display signal ports comprises: a first red display signal port, receiving a first red display signal and connected to a fourth data line; a first green display signal port, receiving a first green display signal and connected to a fifth data line; a first blue display signal port, receiving a first blue display signal and connected to a sixth data line.

According to one aspect of the present disclosure, the plurality of fixed resistors comprises: a first fixed resistor used for connecting to the first red enable signal port and the first green enable signal port; a second fixed resistor used for connecting to the first green enable signal port and the first blue enable signal port; a third fixed resistor used for connecting to the first blue enable signal port and the first red display signal port; a fourth fixed resistor used for connecting to the first red display signal port and the first green display signal port; a fifth fixed resistor used for connecting to the first green display signal port and the first blue display signal port

According to one aspect of the present disclosure, the plurality of fixed resistors are formed in series.

According to one aspect of the present disclosure, wherein values of the plurality of fixed resistor are equal.

According to one aspect of the present disclosure, wherein values of the plurality of constants resistor are greater than or equal to 3000 ohms and less than or equal to 100000 ohms.

The display panel of the present disclosure sets the fixed resistor with relatively greater resistance between the plurality of test signal ports to connect to two adjacent test signal ports. Since the resistance of the fixed resistor is very large, usually thousands of ohms, current between the two adjacent test signal ports is 0, regardless of testing or when the display panel is working normally. In other words, the fixed resistor does not affect the input data signal of the display panel. After the test is over, when a voltage is applied to the test signal ports to invalidate the test data ports, the test data port connected to the plurality of fixed resistors have the same voltage, since the voltage across the fixed resistor is the same. Even if some of the test signal ports are damaged, and cannot received the voltage, the test signal ports can obtain the same voltage as the adjacent test data ports through the fixed resistor, thereby ensuring that the test signal ports are invalid when the display panel is working normally. The present disclosure can resolve the technical issue that the display signal cannot be received by the display panel after the cell test.

### DESCRIPTION OF DRAWINGS

FIG. 1 is a schematic view of port of display panel of the prior art.

FIG. 2 is a schematic view of port of display panel of one of embodiment of the present disclosure.

### DETAILED DESCRIPTION OF PREFERRED EMBODIMENTS

The following description of the embodiments with reference to the appended drawings is used for illustrating specific embodiments which may be used for carrying out the present disclosure. The directional terms described by the present disclosure, such as “upper”, “lower”, “front”, “back”, “left”, “right”, “inner”, “outer”, “side”, etc., are only directions by referring to the accompanying drawings. Thus, the adopted directional terms are used to describe and understand the present disclosure, but the present disclosure is not limited thereto. In figures, elements with similar structures are indicated by the same numbers.

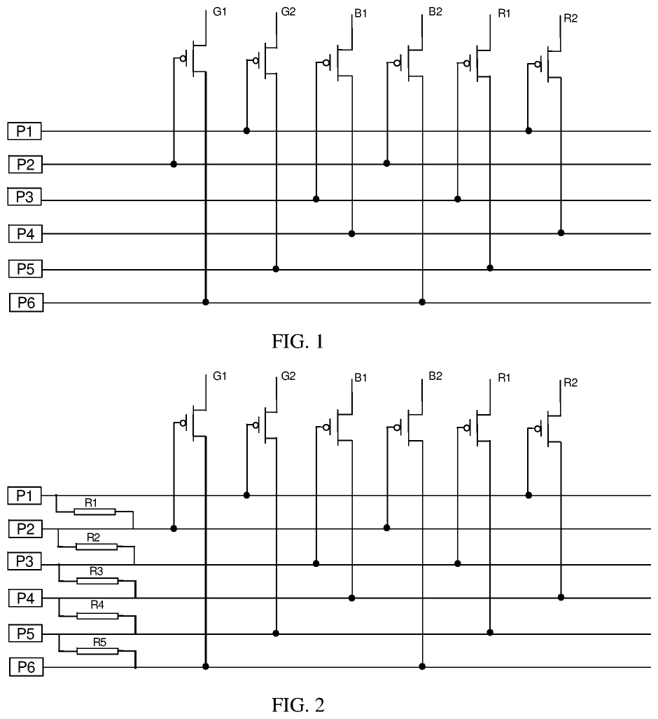

First is a brief descripting of the prior art. Referring to FIG. 1, FIG. 1 is a schematic view of port of display panel of the prior art. The display panel comprises six test data ports (P1, P2, P3, P4, P5, and P6) and six display data ports (G1, G2, B1, B2 R1, and R2). During a cell test, the display data ports have no signal received, while the test signal is received by the display panel from the test data ports. After passing the cell test, the display data is received by the display panel from the display data ports. At this time, in order to prevent the test data ports from forming interference on the display panel, it is necessary have an invalid voltage received by the test data ports. The invalid voltage is usually a high voltage with a voltage greater than 30V, which will put the test data ports in an invalid state. Since the test data ports are prone to damage and interference, this results in inability of valid voltage to be received, and the test data ports will remain in a floating state, leading to inability of corresponding display signal to be received by the display panel and causing abnormal display.

Thus, the present disclosure provides a display panel to resolve the technical issue that the display signal cannot be received by the display panel after the cell test. The present disclosure is described in detail with reference to the accompanying drawings hereinafter. Referring to FIG. 2, FIG. 2 is a schematic view of port of display panel of one of embodiment of the present disclosure. The display panel comprises a plurality of test data ports, and the plurality of test data ports are connected to a data line within the display panel and transfer test data to the display panel. The display panel also comprises a plurality of fixed resistors, and any two adjacent test data ports are connected through the fixed resistors. Value of the fixed resistors are greater than or equal to 1000 ohms.

In the present disclosure, a number of the test data ports is N, a number of the fixed resistors is N-1, wherein N is a positive integer that is greater than or equal to 2. In the present embodiment, the number of the test data ports is 6, and the number of the fixed resistors is 5.

In the present disclosure, the display panel comprises a plurality of display data ports, and the plurality of display data ports are connected to the data lines within the display panel and transfer test data to the display panel. Each of the data lines corresponds to each of the test data ports and each of the display data ports, and the test data ports and the display data ports are disposed in parallel in the same data line.

In the present embodiment, the test data ports comprise a plurality of first enable ports and a plurality of first display ports. The plurality of first enable signal ports comprise: a first red enable signal port P1, a first green enable signal port P2, and a first blue enable signal port P3. The plurality of first display signal ports comprise: a first red display signal port P4, a first green display signal port P5, and a first blue display signal port P6.

The first red enable signal port P1 receives a first red enable signal and connects to a first data line. The first green enable signal port P2 receives a first green enable signal and connects to a second data line. The first blue enable signal port P3 receives a first blue enable signal and connects to a third data line. The first red display signal port P4 receives a first red display signal and connects to a fourth data line. The first green display signal port P5 receives a first green display signal and connects to a fifth data line. The first blue display signal port P6 receives a first blue display signal and connects to a sixth data line.

In the present embodiment, the display data ports comprise a plurality of second enable ports and a plurality of second display ports. The plurality of second enable signal ports comprise: a second red enable signal port R1, a second green enable signal port G1, and a second blue enable signal port B1. The plurality of second display signal ports comprise: a second red display signal port R2, a second green display signal port G2, and a second blue display signal port B2.

Referring to FIG. 2, in the present disclosure, the plurality of fixed resistors comprise: a first fixed resistor R1, a second fixed resistor R2, a third fixed resistor R3, a fourth fixed resistor R4, and a fifth fixed resistor R5. The first fixed resistor R1 is used for connecting to the first red enable signal port P1 and the first green enable signal port P2. The second fixed resistor R2 is used for connecting to the first green enable signal port P2 and the first blue enable signal port P3. The third fixed resistor R3 is used for connecting to the first blue enable signal port P3 and the first red display signal port P4. The fourth fixed resistor R4 is used for connecting to the first red display signal port P4 and the first green display signal port P5. The fifth fixed resistor R5 is used for connecting to the first green display signal port P5 and the first blue display signal port P6.

In the present embodiment, the first fixed resistor R1, the second fixed resistor R2, the third fixed resistor R3, the fourth fixed resistor R4, and the fifth fixed resistor R5 are disposed in series, and the first fixed resistor R1, the second fixed resistor R2, the third fixed resistor R3, the fourth fixed resistor R4, and the fifth fixed resistor R5 have the same resistance. Preferably, values of the plurality of fixed resistors are greater than or equal to 3000 ohms and less than or equal to 100000 ohms. Usually, the plurality of fixed resistors can be formed in a polysilicon layer of a thin film transistor layer of the display panel. In practice, the area of the fixed resistor can be adjusted by adjusting the thickness and area of the polysilicon layer.

The display panel of the present disclosure sets the fixed resistor with relatively greater resistance between the plurality of test signal ports to connect to two adjacent test signal ports. Since the resistance of the fixed resistor is very large, usually thousands of ohms, current between the two adjacent test signal ports is 0, regardless of testing or when the display panel is working normally. In other words, the fixed resistor does not affect the input data signal of the display panel. After the test is over, when a voltage is applied to the test signal ports to invalidate the test data ports, the test data port connected to the plurality of fixed resistors have the same voltage, since the voltage across the fixed resistor is the same. Even if some of the test signal ports are damaged, and cannot received the voltage, the test signal ports can obtain the same voltage as the adjacent test data ports through the fixed resistor, thereby ensuring that the test signal ports are invalid when the display panel is working normally. The present disclosure can resolve the technical issue that the display signal cannot be received by the display panel after the cell test.

As mentioned above, while the present disclosure has been disclosed via preferred embodiments as above, the preferred embodiments are not intended to limit the disclosure. Those skilled in the art can make various modifications and alterations without departing from the spirit and scope of the disclosure. The scope of protection of the disclosure is defined by the claims.

What is claimed is:

1. A display panel, wherein the display panel comprises:
a plurality of test data ports, the plurality of test data ports connected to data lines within the display panel to transfer test data to the display panel;
wherein the display panel further comprises a plurality of fixed resistors;
any two adjacent test data ports are connected through the fixed resistor, the values of fixed resistors are equal to or greater than 1000 ohms; and
wherein the plurality of fixed resistors are disposed in series.

2. The display panel as claimed in claim 1, wherein a number of the test data ports is N and a number of the fixed resistors is N-1, wherein N is a positive integer and greater than or equal to 2.

3. The display panel as claimed in claim 1, wherein the display panel comprises a plurality of display data ports, the plurality of display data ports are connected to the data line within display panel and transferring test data to the display panel, wherein
each of the data line is corresponding to each of the test data port and each of the display data port, and the test data port and the display data port are formed in parallel in the same data line.

4. The display panel as claimed in claim 3, wherein the test data ports comprise a plurality of first enable signal ports and a plurality of first display signal ports.

5. The display panel as claimed in claim 4, wherein the plurality of first enable signal ports comprise:
a first red enable signal port receiving a first red enable signal and connected to a first data line;
a first green enable signal port receiving a first green enable signal and connected to a second data line; and
a first blue enable signal port receiving a first blue enable signal and connected to a third data line.

6. The display panel as claimed in claim 5, wherein the plurality of first display signal ports comprise:
a first red display signal port receiving a first red display signal and connected to a fourth data line;
a first green display signal port receiving a first green display signal and connected to a fifth data line; and
a first blue display signal port receiving a first blue display signal and connected to a sixth data line.

7. The display panel as claimed in claim 6, wherein the plurality of fixed resistors comprise:
a first fixed resistor used for connecting to the first red enable signal port and the first green enable signal port;
a second fixed resistor used for connecting to the first green enable signal port and the first blue enable signal port;
a third fixed resistor used for connecting to the first blue enable signal port and the first red display signal port;
a fourth fixed resistor used for connecting to the first red display signal port and the first green display signal port; and
a fifth fixed resistor used for connecting to the first green display signal port and the first blue display signal port.

8. The display panel as claimed in claim 1, wherein values of the plurality of fixed resistors are same.

9. The display panel as claimed in claim 1, wherein values of the plurality of fixed resistors are greater than or equal to 3000 ohms and less than or equal to 100000 ohms.

10. A display panel, wherein the display panel comprises:
a plurality of test data ports, the plurality of test data ports connected to data lines within the display panel to transfer test data to the display panel;
wherein the display panel further comprises a plurality of fixed resistors;
any two adjacent test data ports are connected through the fixed resistor, the values of fixed resistors are equal to or greater than 1000 ohms.

11. The display panel as claimed in claim 10, wherein a number of the test data ports is N and a number of the fixed resistors is N-1, wherein N is a positive integer and greater than or equal to 2.

12. The display panel as claimed in claim 10, wherein the display panel comprises a plurality of display data ports, the plurality of display data ports are connected to the data line within display panel and transferring test data to the display panel, wherein
each of the data line is corresponding to each of the test data port and each of the display data port, and the test data port and the display data port are formed in parallel in the same data line.

13. The display panel as claimed in claim 12, wherein the test data ports comprise a plurality of first enable signal ports and a plurality of first display signal ports.

14. The display panel as claimed in claim 13, wherein the plurality of first enable signal ports comprise:
a first red enable signal port receiving a first red enable signal and connected to a first data line;
a first green enable signal port receiving a first green enable signal and connected to a second data line; and
a first blue enable signal port receiving a first blue enable signal and connected to a third data line.

15. The display panel as claimed in claim 14, wherein the plurality of first display signal ports comprise:
a first red display signal port receiving a first red display signal and connected to a fourth data line;
a first green display signal port receiving a first green display signal and connected to a fifth data line; and
a first blue display signal port receiving a first blue display signal and connected to a sixth data line.

16. The display panel as claimed in claim 15, wherein the plurality of fixed resistors comprise:
a first fixed resistor used for connecting to the first red enable signal port and the first green enable signal port;
a second fixed resistor used for connecting to the first green enable signal port and the first blue enable signal port;
a third fixed resistor used for connecting to the first blue enable signal port and the first red display signal port;
a fourth fixed resistor used for connecting to the first red display signal port and the first green display signal port; and
a fifth fixed resistor used for connecting to the first green display signal port and the first blue display signal port.

17. The display panel as claimed in claim 10, wherein the plurality of fixed resistors are disposed in series.

18. The display panel as claimed in claim 10, wherein values of the plurality of fixed resistors are same.

19. The display panel as claimed in claim 10, wherein values of the plurality of fixed resistors are greater than or equal to 3000 ohms and less than or equal to 100000 ohms.
